(19) United States
(12) Patent Application Publication
(10) Pub. No.: US 2025/0248288 A1
(43) Pub. Date: Jul. 31, 2025

(54) DISPLAY DEVICE

(71) Applicant: Japan Display Inc., Tokyo (JP)

(72) Inventor: Toshiharu MATSUSHIMA, Tokyo (JP)

(73) Assignee: Japan Display Inc., Tokyo (JP)

(21) Appl. No.: 19/033,547

(22) Filed: Jan. 22, 2025

(30) Foreign Application Priority Data
Jan. 26, 2024 (JP) 2024-010168

(51) Int. Cl. H10K 59/80; H10K 59/121; H10K 102/00

(52) U.S. Cl. CPC H10K 59/879; H10K 59/1213; H10K 59/87; H10K 2102/351

(57) ABSTRACT

According to one embodiment, a display device comprises an insulating layer, a first lower electrode and a second lower electrode which are provided on the insulating layer, a rib overlapping the first lower electrode and the second lower electrode and having a single pixel aperture, a partition which includes a lower portion provided above the rib and an upper portion provided on the lower portion, an organic layer in contact with the first lower electrode and the second lower electrode through the pixel aperture and including a light emitting layer, and a lens having a convex shape and overlapping the aperture, the organic layer being in contact with the insulating layer through the pixel aperture between the first lower electrode and the second lower electrode.

### CROSS-REFERENCE TO RELATED APPLICATIONS

This application is based upon and claims the benefit of priority from Japanese Patent Application No. 2024-010168, filed Jan. 26, 2024, the entire contents of which are incorporated herein by reference.

### FIELD

Embodiments described herein relate generally to a display device.

### BACKGROUND

In recent display devices, it is requested to vary viewing angles achieving a certain contrast. For example, in display devices mounted on a vehicle such as an automobile, a viewing angle control is requested in which a displayed image is visually-recognizable from a side of a passenger seat and, in contrast, a displayed image is not visually-recognizable from a side of a driver seat, for example, at the time of driving.

### BRIEF DESCRIPTION OF THE DRAWINGS

FIG. 1 is a view showing a configuration example of a display device of a present embodiment.

FIG. 2 is a circuit diagram showing an example of a circuit configuration of a subpixel.

FIG. 3 is a schematic plan view showing an example of the layout of subpixels.

FIG. 4 is a plan view showing an example of the layout of partitions and lenses shown in FIG. 3.

FIG. 5 is a cross-sectional view showing a configuration example of the display device along line A-A′ in FIG. 4.

FIG. 6 is a view for explaining the function of lenses shown in FIG. 5.

FIG. 7 is a view showing a state where the display device mounted on a vehicle-mounted device displays an image in a first mode.

FIG. 8 is a view showing a state where the display device mounted on a vehicle-mounted device displays an image in a second mode.

FIG. 9 is a schematic plan view showing another example of the layout of subpixels.

FIG. 10 is a plan view showing an example of the layout of partitions and lenses shown in FIG. 9.

FIG. 11 is a view for explaining the function of the lenses shown in FIG. 10.

FIG. 12 is a schematic plan view showing another example of the layout of subpixels.

FIG. 13 is a plan view showing an example of the layout of partitions and lenses shown in FIG. 12.

FIG. 14 is a view for explaining the function of the lenses shown in FIG. 13.

FIG. 15 is a schematic plan view showing another example of the layout of subpixels.

FIG. 16 is a plan view showing an example of the layout of partitions and lenses shown in FIG. 15.

FIG. 17 is a schematic plan view showing another example of the layout of subpixels.

FIG. 18 is a plan view showing an example of the layout of partitions and lenses show in FIG. 17.

FIG. 19 is a cross-sectional view showing a configuration example of the display device along line B-B′ and line C-C′ in FIG. 18.

FIG. 20 is a schematic plan view showing another example of the layout of subpixels.

FIG. 21 is a plan view showing an example of the layout of partitions and partitions show in FIG. 20.

FIG. 22 is a circuit diagram showing another example of the circuit configuration of a subpixel.

FIG. 23 is a schematic plan view showing another example of the layout of subpixels.

FIG. 24 is a plan view showing an example of the layout of partitions and lenses show in FIG. 23.

FIG. 25 is a cross-sectional view showing a configuration example of the display device along line D-D′ in FIG. 24.

FIG. 26 is a view for explaining the function of lenses shown in FIG. 25.

### DETAILED DESCRIPTION

In general, according to one embodiment, a display device comprises: a substrate; an insulating layer provided above the substrate; a first lower electrode and a second lower electrode, which are provided on the insulating layer and are spaced apart from each other; a rib overlapping the first lower electrode and the second lower electrode and having a single pixel aperture; a partition, which includes a lower portion provided above the rib and having a conductivity and an upper portion provided on the lower portion and having an aperture surrounded by an edge portion projecting from a side surface of the lower portion; an organic layer in contact with the first lower electrode and the second lower electrode through the pixel aperture and including a light emitting layer; an upper electrode covering the organic layer and in contact with the lower portion; and a lens having a convex shape projecting toward a side opposite to the substrate and overlapping the aperture, the organic layer being in contact with the insulating layer through the pixel aperture between the first lower electrode and the second lower electrode.

Embodiments described herein can provide a display device capable of limiting viewing angles.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis and a Z-axis orthogonal to each other are described to facilitate understanding as needed. A direction parallel to the X-axis is referred to as an X direction. A direction parallel to the Y-axis is referred to as a Y direction. A direction parallel to the Z-axis is referred to as a Z direction. When various elements are viewed parallel to the Z direction, the appearance is defined as a plan view.

The display device of the present embodiment is an organic electroluminescent display device comprising an organic light emitting diode (OLED) as a display element, and can be mounted on televisions, personal computers, vehicle-mounted devices, tablet terminals, smartphones, mobile phones, and the like.

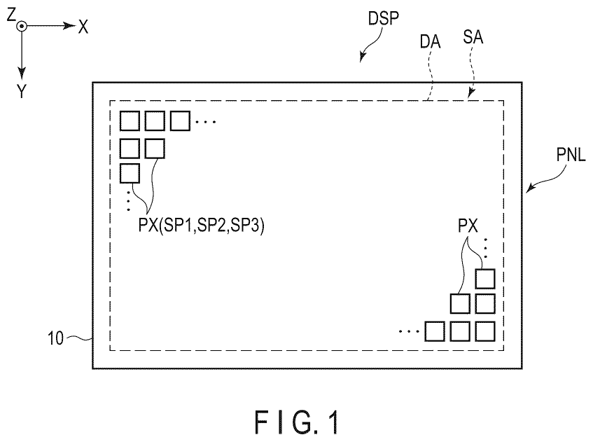

FIG. 1 is a view showing a configuration example of a display device DSP of a present embodiment. The display device DSP comprises a display panel PNL comprising a display area DA which displays an image and a surrounding area SA located on an external side relative to the display area DA on an insulating substrate 10. The substrate 10 may be glass or a resinous film having flexibility.

In FIG. 1, the substrate 10 has a rectangular shape having long sides parallel to the X direction in plan view. The shape of the substrate 10 in a plan view is not limited to this example and may be another shape such as a rectangular shape having long sides parallel to the Y direction, a square shape, a circular shape, or an elliptic shape.

The display area DA comprises a plurality of pixels PX arranged in a matrix in the X direction and the Y direction. Each pixel PX includes a plurality of subpixels SP. As an example, each pixel PX includes a subpixel SP1 which exhibits a first color, a subpixel SP2 which exhibits a second color, and a subpixel SP3 which exhibits a third color. The first, second, and third colors are colors different from each other. Each pixel PX may include a subpixel SP which exhibits another color such as white in addition to the subpixels SP1, SP2, and SP3 or instead of one of the subpixels SP1, SP2, and SP3.

Although not described in detail, a terminal for connecting an IC chip and a flexible printed circuit is provided in the surrounding area SA.

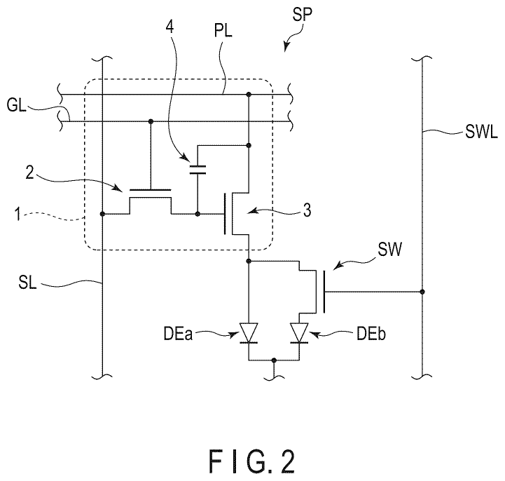

FIG. 2 is a circuit diagram showing an example of the circuit configuration of the subpixel SP. The subpixel SP comprises a pixel circuit 1 and display elements DEa and DEb driven by the pixel circuit 1. The pixel circuit 1 comprises a pixel switch 2, a drive transistor 3, a capacitor 4, and a switching element SW. The pixel switch 2, the drive transistor 3, and the switching element SW each are composed of, for example, a thin film transistor.

A gate electrode of the pixel switch 2 is connected to a scanning line GL. Either a source electrode or a drain electrode of the pixel switch 2 is connected to a signal line SL. The other is connected to a gate electrode of the drive transistor 3 and the capacitor 4. In the drive transistor 3, either the source electrode or the drain electrode is connected to a power line PL and the capacitor 4. The other is connected to the anode of the display element DEa and also to either a source electrode or a drain electrode of the switching element SW. The other of the source electrode and the drain electrode of the switching element SW is electrically connected to the anode of the display element DEb. The display element DEa (a first display element) is serially connected to the drive transistor 3. The display element DEb (a second display element) is parallely connected to the display element DEa. The switching element SW is provided between the drive transistor 3 and the display element DEb. The gate electrode of the switching element SW is connected to a switching line SWL. The switching line SWL is supplied with a signal for switching between a first mode and a second mode to be described later.

The configuration of the pixel circuit 1 is not limited to the example shown in the figure. For example, the pixel circuit 1 may comprise more thin-film transistors and capacitors.

The display elements DEa and DEb are an organic light emitting diode (OLED) as light emitting elements and thus are called an organic EL element as well.

The display device DSP comprises a first mode in which the switching element SW is in off state, and a second mode in which the switching element SW is in on state.

The display device DSP in the first mode has

the off-state switching element SW, and thus has the conductivity between the drive transistor 3 and the anode of the display element DEa but does not have the conductivity between the drive transistor 3 and the anode of the display element DEb. Therefore, in the first mode, the display element DEa emits light, but the display element DEb does not emit light.

The display device DSP in the second mode has the on-state switching element SW and thus has the conductivity between the drive transistor 3 and the display element DEa and the conductivity between the drive transistor 3 and the display element DEb. Therefore, in the second mode, the display elements DEa and DEb both emit light.

In this manner, switching between the first mode and the second mode can switch light-emitting state of the display element DEb.

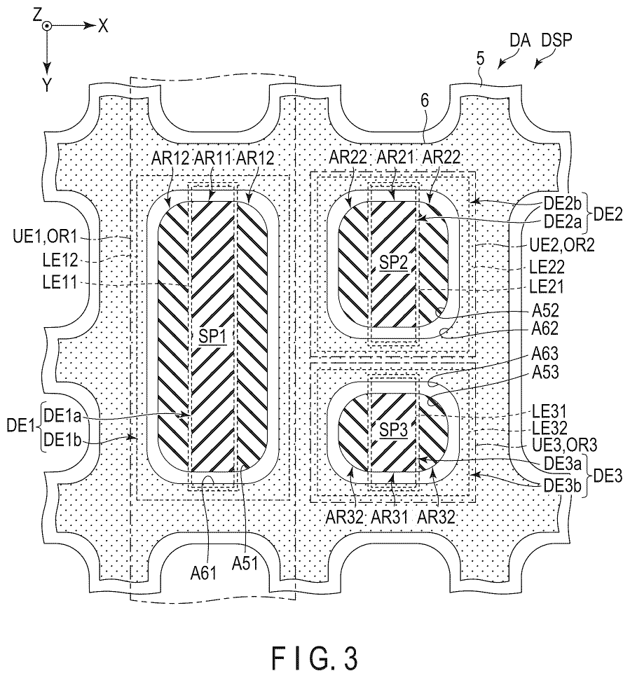

FIG. 3 is a schematic plan view showing an example of the layout of the subpixels SP1, SP2, and SP3. In the example of FIG. 3, the subpixels SP2, and SP3 are arranged in the Y direction. The subpixels SP1 and SP2 are arranged in the X direction, and the subpixels SP1 and SP3 are arranged in the X direction.

When the subpixels SP1, SP2, and SP3 are arranged in this layout, in the display area DA, a column in which the subpixels SP2 and SP3 are alternately arranged in the Y direction and a column in which the plurality of subpixels SP1 are repeatedly arranged in the Y direction are formed. These columns are alternately arranged in the X direction.

The layout of the subpixels SP1, SP2, and SP3 is not limited to the example of FIG. 3. As another example, the subpixels SP1, SP2, and SP3 in each pixel PX are arranged in an order in the X direction.

An inorganic insulating layer 5 and a partition 6 are provided in the display area DA. The inorganic insulating layer 5 has apertures A51, A52, and A53 (pixel apertures) in the respective subpixels SP1, SP2, and SP3. The inorganic insulating layer 5 having these apertures A51, A52, and A53 is called a rib as well.

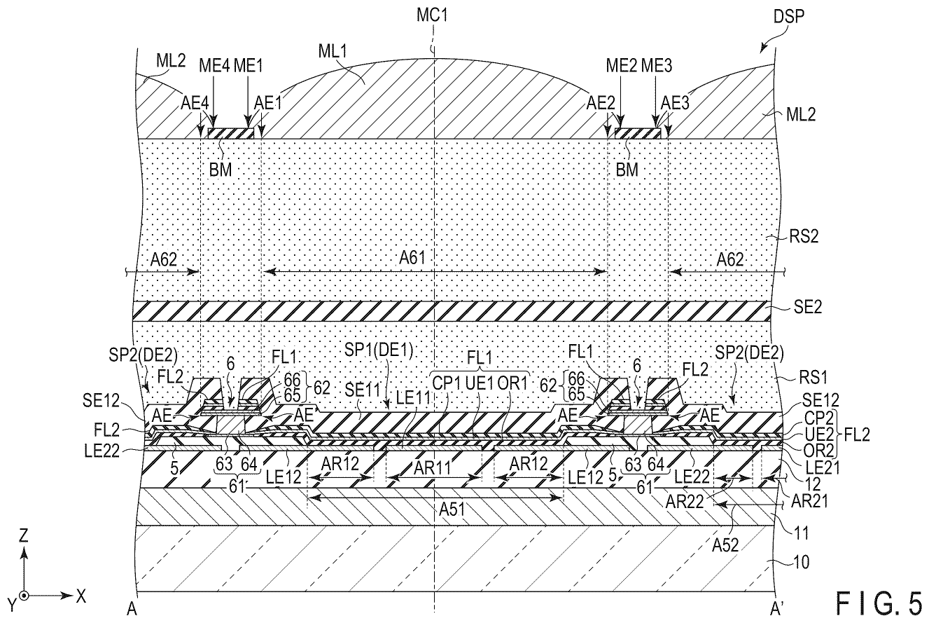

The partition 6 overlaps the inorganic insulating layer 5 in plan view. The partition 6 is formed into a grating shape surrounding the apertures A51, A52, and A53. The partition 6 includes apertures A61, A62, and A63 surrounded by an edge portion of an upper portion of the partition 6, which is to be described with reference to FIG. 5. The aperture A61 surrounds the aperture A51 in the subpixel SP1. The aperture A62 surrounds the aperture A52 in the subpixel SP2. The aperture A63 surrounds the aperture A53 in the subpixel SP3. In the example of FIG. 3, a corner portion of each of the apertures A51, A52, A53, A61, A62, and A63 has a round shape. The corner portion may have a right angle. Each of the apertures A51, A52, A53, A61, A62, and A63 may have other shapes such as a circular shape and an elliptic shape. The partition 6 has conductivity and is electrically connected to a terminal having a common potential, of a plurality of terminals provided in the surrounding area SA shown in FIG. 1.

The subpixels SP1, SP2, and SP3 comprise display elements DE1, DE2, and DE3, respectively, as the display elements DE. The display elements DE1, DE2, and DE3 have light emitting layers formed of respective materials emitting light in different colors.

The display element DE1 of the subpixel SP1 comprises display elements DE1a and DE1b. The display element DE1a includes a lower electrode LE11, an upper electrode UE1, and an organic layer OR1. The display element DE1b includes a lower electrode LE12, the upper electrode UE1, and the organic layer OR1. The upper electrode UE1 and the organic layer OR1 continuously overlap the lower electrodes LE11 and LE12. Each of the lower electrodes LE11 and LE12, the upper electrode UE1, and the organic layer OR1 overlaps the apertures A51 and A61. The peripheral portion of each of the organic layer OR1 and the upper electrode UE1 overlaps the inorganic insulating layer 5 in plan view. The organic layer OR1 includes a light emitting layer which emits light in, for example, a green wavelength range.

The display element DE2 of the subpixel SP2 includes display elements DE2a and DE2b. The display element DE2a includes a lower electrode LE21, an upper electrode UE2, and an organic layer OR2. The display element DE2b includes a lower electrode LE22, the upper electrode UE2, and the organic layer OR2. The upper electrode UE2 and the organic layer OR2 continuously overlap the lower electrodes LE21 and LE22. Each of the lower electrodes LE21 and LE22, the upper electrode UE2, and the organic layer OR2 overlaps the apertures A52 and A62. The peripheral portion of each of the organic layer OR2 and the upper electrode UE2 overlaps the inorganic insulating layer 5 in plan view. The organic layer OR2 includes a light emitting layer which emits light in, for example, a blue wavelength range.

The display element DE3 of the subpixel SP3 includes display elements DE3a and DE3b. The display element DE3a includes a lower electrode LE31, an upper electrode UE3, and an organic layer OR3. The display element DE3b includes a lower electrode LE32, the upper electrode UE3, and the organic layer OR3. The upper electrode UE3 and the organic layer OR3 continuously overlap the lower electrodes LE31 and LE32. Each of the lower electrodes LE31 and LE32, the upper electrode UE3, and the organic layer OR3 overlaps the apertures A53 and A63. The peripheral portion of each of the organic layer OR3 and the upper electrode UE3 overlaps the inorganic insulating layer 5 in plan view. The organic layer OR3 includes a light emitting layer which emits light in, for example, a red wavelength range.

The display elements DE1a, DE2a, and DE3a each correspond to the display element DEa shown in FIG. 2. The display elements DE1b, DE2b, and DE3b each correspond to the display element DEb shown in FIG. 2.

In the example of FIG. 3, each of the lower electrodes LE11, LE21, and LE31 has a rectangular shape having long sides parallel to the Y direction. Further, short sides parallel to the X direction of each of the lower electrodes LE11, LE21, and LE31 overlap the inorganic insulating layer 5 and the partition 6 in plan view. These short sides may not overlap the inorganic insulating layer 5 and the partition 6 in plan view. The lower electrodes LE11, LE21, and LE31 each may have shapes other than a rectangular shape.

The lower electrodes LE11 and LE12 are spaced apart from each other. In the example shown in FIG. 3, the lower electrode LE11 is surrounded by the lower electrode LE12 in plan view. The lower electrodes LE21 and LE22 are spaced apart from each other. In the example shown in FIG. 3, the lower electrode LE21 is surrounded by the lower electrode LE22 in plan view. The lower electrodes LE31 and LE32 are spaced apart from each other. In the example shown in FIG. 3, the lower electrode LE31 is surrounded by the lower electrode LE32 in plan view.

For example, the lower electrode LE11 correspond to the anode of the display element DE1a, the lower electrode LE21 correspond to the anode of the display element DE2a, and the lower electrode LE31 correspond to the anode of the display element DE3a. For example, the lower electrode LE12 correspond to the anode of the display element DE1b, the lower electrode LE22 correspond to the anode of the display element DE2b, and the lower electrode LE32 correspond to the anode of the display element DE3b. The lower electrodes LE11, LE21, and LE31 each are connected to the source electrode or the drain electrode of the drive transistor 3 in each subpixel SP shown in FIG. 2. The lower electrodes LE12, LE22, and LE32 each are connected to the source electrode or the drain electrode of the switching element SW in each subpixel SP shown in FIG. 2. The upper electrodes UE1, UE2, and UE3 each correspond to the cathode of the display elements or a common electrode and are in contact with the partition 6.

The organic layer OR1 includes a first area AR11 corresponding to the area where the aperture A51 and the lower electrode LE11 overlap each other and a second area AR12 corresponding to the area where the aperture A51 and the lower electrode LE12 overlap each other in plan view. The organic layer OR2 includes a first area AR21 corresponding to the area where the aperture A52 and the lower electrode LE21 overlap each other and a second area AR22 corresponding to the area where the aperture A52 and the lower electrode LE22 overlap each other in plan view. The organic layer OR3 includes a first area AR31 corresponding to the area where the aperture A53 and the lower electrode LE31 overlap each other and a second area AR32 corresponding to the area where the aperture A53 and the lower electrode LE32 overlap each other in plan view.

In the example of FIG. 3, the first areas AR11, AR21, and AR31 and the second areas AR12, AR22, and AR32 are indicated by hatch lines.

As described above, in the display device DSP in the first mode, the display element DEa emits light, but the display element DEb does not emit light, these display elements being shown in FIG. 2. Thus, in the first mode, the first areas AR11, AR21, and AR31 emit light, but the second areas AR12, AR22, and AR32 do not emit light.

As described above, in the display device DSP in the second mode, the display elements DEa and DEb both emit light, these elements being shown in FIG. 2. Thus, in the second mode, the first areas AR11, AR21, and AR31 and the second areas AR12, AR22, and AR32 both emit light.

In the example of FIG. 3, the outer shapes of the lower electrodes LE11, LE12, LE21, LE22, LE31, and LE32 are indicated by dotted lines, and the outer shapes of the organic layers OR1, OR2, and OR3 and the upper electrodes UE1, UE2, and UE3 are indicated by one-dot chain line. The outer shapes of the lower electrode, the organic layer, and the upper electrode shown in the figure may not reflect their exact shapes.

In the example of FIG. 3, the area of the aperture A51, the area of the aperture A52, and the area of the aperture A53 are different from one another. The area of the aperture A51 is greater than the area of the aperture A52, and the area of the aperture A52 is greater than the area of the aperture A53. The total area of the lower electrodes LE11 and LE12 exposed from the aperture A51 is greater than the total area of the lower electrodes LE21 and LE22 exposed from the aperture A52. The total area of the lower electrodes LE21 and LE22 exposed from the aperture A52 is greater than the total area of the lower electrodes LE31 and LE32 exposed from the aperture A53. The magnitude relationship among the apertures A51, A52, and A53 is not limited to the illustrated example.

Similarly, in the example of FIG. 3, the area of the aperture A61, the area of the aperture A62, and the area of the aperture A63 are different from one another. The area of the aperture A61 is greater than the area of the aperture A62, and the area of the aperture A62 is greater than the area of the aperture A63. The magnitude relationship among the apertures A61, A62, and A63 is not limited to the illustrated example.

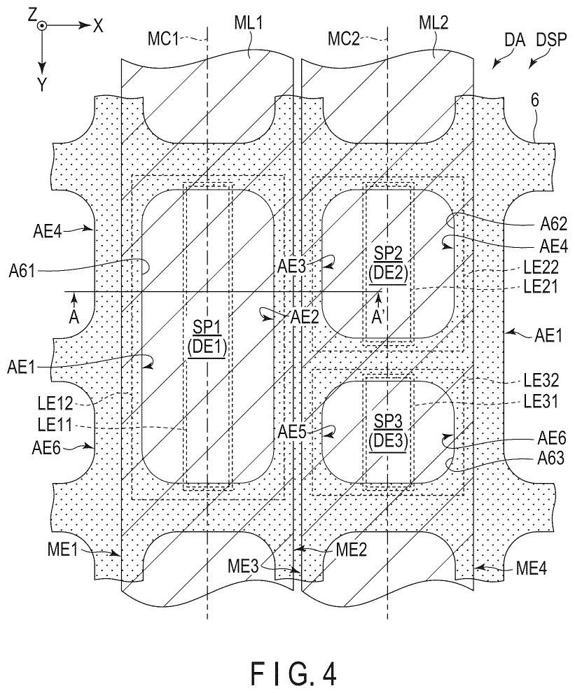

FIG. 4 is a plan view showing an example of the layout of a partition 6 and lenses ML1 and ML2 shown in FIG. 3. FIG. 4 omits the illustration of the inorganic insulating layer, the organic insulating layer, and the upper electrode, and the like.

In the aperture A61, the edge portion of the partition 6 includes aperture edges AE1 and AE2. The aperture edges AE1 and AE2 are parallel to the Y direction. The aperture edges AE1 and AE2 face each other along the X direction. In the example shown in FIG. 4, the aperture edges AE1 and AE2 overlap the lower electrode LE12 in plan view.

In the aperture A62, the edge portion of the partition 6 includes aperture edges AE3 and AE4. The aperture edges AE3 and AE4 are parallel to the Y direction. The aperture edges AE3 and AE4 face each other along the X direction. In the example shown in FIG. 4, the aperture edges AE3 and AE4 overlap the lower electrode LE22 in plan view.

In the aperture A63, the edge portion of the partition 6 includes aperture edges AE5 and AE6. The aperture edges AE5 and AE6 are parallel to the Y direction. The aperture edges AE5 and AE6 face each other in the X direction. In the example shown in FIG. 4, the aperture edges AE5 and AE6 overlap the lower electrode LE32 in plan view.

The display device DSP further comprises the lenses ML1 and ML2. Each of the lenses ML1 and ML2 extends in the Y direction. The lens ML1 overlaps the aperture A61 and the display element DE1 in plan view. In the example of FIG. 4, the lens ML1 covers the aperture A61. The lens ML2 overlaps the apertures A62 and A63 and the display elements DE2 and DE3 in plan view. In the example of FIG. 4, the lens ML2 continuously covers the apertures A62 and A63.

The lens ML1 includes a lens edge ME1 (a first lens edge), a lens edge ME2 (a second lens edge), and a center line MC1. The lens edges ME1 and ME2 and the center line MC1 are parallel to the Y direction. In the illustrated example, the lens edges ME1 and ME2 each overlap the partition 6 in plan view. In the illustrated example, the lens edge ME1 is located between the aperture edges AE1 and AE4 and between the aperture edges AE1 and AE6 in the X direction. In the illustrated example, the lens edge ME2 is located between the aperture edges AE2 and AE3 and between the aperture edges AE2 and AE5 in the X direction.

The center line MC1 is located between the aperture edges AE1 and AE2 in the X direction and overlap the aperture A61 and the display element DE1 in plan view. In the illustrated example, the center line MC1 overlaps the lower electrode LE11 in plan view.

The lens ML2 includes a lens edge ME3 (a first lens edge), a lens edge ME4 (a second lens edge), and a center line MC2. The lens edges ME3 and ME4 and the center line MC2 are parallel to the Y direction. In the illustrated example, the lens edges ME3 and ME4 each overlap the partition 6 in plan view. In the illustrated example, the lens edge ME3 is located between the aperture edges AE2 and AE3 and between the aperture edges AE2 and AE5 in the X direction. In the illustrated example, the lens edge ME4 is located between the aperture edges AE1 and AE4 and between the aperture edges AE1 and AE6 in the X direction.

The center line MC2 is located between the aperture edges AE3 and AE4 and between the aperture edges AE5 and AE6 in the X direction and overlaps the apertures A62 and A63 and the display elements DE2 and DE3 in plan view. In the illustrated example, the center line MC2 overlaps the lower electrodes LE21 and LE31 in plan view.

In this specification, the term “the center line of a lens” signifies a line connecting a plurality of principal points of the lens. A principal point is a point at which the main surface of the lens and optical axis are orthogonal to each other. The main surface includes an intersection of a light beam before being made incident and light beam after being emitted in a case of making a light beam parallel to an optical axis incident on the lens and intersects the optical axis.

FIG. 5 is a cross-sectional view showing a configuration example of the display device DSP along line A-A′ in FIG. 4. The following describes the subpixels SP1 and SP2. The subpixel SP3 has the same configuration as those of the subpixels SP1 and SP2.

A circuit layer 11 is provided on the substrate 10. The circuit layer 11 includes various circuits such as the pixel circuit 1 and various lines such as the scanning line GL, the signal line SL, and a power line PL shown in FIG. 2. The circuit layer 11 is covered with an insulating layer 12. The insulating layer 12 is an organic insulating layer which planarizes uneven parts formed by the circuit layer 11.

The lower electrodes LE11, LE12, LE21, and LE22 are provided on the insulating layer 12 and are spaced apart from one another. The inorganic insulating layer 5 is provided on the insulating layer 12 and the lower electrodes LE12 and LE22. The aperture A51 of the inorganic insulating layer 5 overlaps the lower electrodes LE11 and LE12. The aperture A52 overlaps the lower electrodes LE21 and LE22. The inorganic insulating layer 5 covers the insulating layer 12 between the lower electrodes LE12 and LE22. The lower electrodes LE11 and LE12 are connected to the pixel circuit 1 of the subpixel SP1 through a contact hole provided in the insulating layer 12. The lower electrodes LE21 and LE22 are connected to the pixel circuit 1 of the subpixel SP2 through a contact hole provided in the insulating layer 12. FIG. 5 omits the illustration of the contact hole in the insulating layer 12.

The partition 6 includes a conductive lower portion 61 provided on the inorganic insulating layer 5 and an upper portion 62 provided on the lower portion 61. The lower portion 61 surrounds each of the display elements DE1 and DE2 in plan view. The upper portion 62 includes an edge portion AE surrounding each of the apertures A61 and A62 in plan view. The edge portion AE projects relative to the side surfaces of the lower portion 61. This shape of the partition 6 is called an overhang shape.

In the illustrated example, the lower portion 61 includes a first conductive layer 63 provided on the inorganic insulating layer 5 and a second conductive layer 64 provided on the first conductive layer 63. For example, the first conductive layer 63 is thinner than the second conductive layer 64. Further, in the illustrated example, both end portions of the first conductive layer 63 project relative to the respective side surfaces of the second conductive layer 64.

The upper portion 62 includes a thin film 65 provided on the second conductive layer 64 and a thin film 66 provided on the thin film 65. Both end portions of each of the thin film 65 and thin film 66 project relative to the side surfaces of the second conductive layer 64. In the illustrated example, the edge portion AE of the thin film 65 surrounds the apertures A61 and A62. The edge portion AE corresponds to, for example, the end portions of the thin film 65.

The organic layer OR1 is in contact with the lower electrodes LE11 and LE12 through the aperture A51 and covers the lower electrodes LE11 and LE12 exposed from the aperture A51. The peripheral portion of the organic layer OR1 is located on the inorganic insulating layer 5. The area where the organic layer OR1 and the lower electrode LE1 are in contact with each other corresponds to the first area AR11. The area where the organic layer OR1 and the lower electrode LE12 are in contact with each other corresponds to the second area AR12. The organic layer OR1 is in contact with the insulating layer 12 through the aperture A51 between the lower electrodes LE11 and LE12. The upper electrode UE1 covers the organic layer OR1 and is in contact with the lower portion 61.

The organic layer OR2 is in contact with the lower electrodes LE21 and LE22 through the aperture A52 and covers the lower electrodes LE21 and LE22 exposed from the aperture A52. The peripheral portion of the organic layer OR2 is located on the inorganic insulating layer 5. The area where the organic layer OR2 and the lower electrode LE21 are in contact with each other corresponds to the first area AR21. The area where the organic layer OR2 and the lower electrode LE22 are in contact with each other corresponds to the second area AR22. The organic layer OR2 is in contact with the insulating layer 12 through the aperture A52 between the lower electrodes LE21 and LE22. The upper electrode UE2 covers the organic layer OR2 and is in contact with the lower portion 61.

In the example of FIG. 5, the subpixel SP1 includes a cap layer CP1 and a first sealing layer SE11, and the subpixel SP2 includes a cap layer CP2 and a first sealing layer SE12. The cap layers CP1 and CP2 function as optical adjustment layers which improve the extraction efficiency of light beams emitted from the respective organic layers OR1 and OR2. The cap layers CP1 and CP2 may be omitted. The cap layer CP1 is provided on the upper electrode UE1. The cap layer CP2 is provided on the upper electrode UE2.

The first sealing layer SE11 is provided on the cap layer CP1, is in contact with the partition 6, and continuously covers each member of the subpixel SP1. The first sealing layer SE12 is provided on the cap layer CP2, is in contact with the partition 6, and continuously covers each member of the subpixel SP2.

In the example of FIG. 5, portions of the organic layer OR1, the upper electrode UE1, and the cap layer CP1 are located on the partition 6 around the subpixel SP1. These portions are spaced apart from portions located in the aperture A51 (the portions constituting the display element DE1) of the organic layer OR1, the upper electrode UE1, and the cap layer CP1.

Similarly, portions of the organic layer OR2, the upper electrode UE2, and the cap layer CP2 are located on the partition 6 around the subpixel SP2. These portions are spaced apart from the portions located in the aperture A52 (the portions constituting the display element DE2) of the organic layer OR2, the upper electrode UE2, and the cap layer CP2.

In the following explanation, a multilayer body including the organic layer OR1, the upper electrode UE1, and the cap layer CP1 is called a stacked film FL1. A multilayer body including the organic layer OR2, the upper electrode UE2, and the cap layer CP2 is called a stacked film FL2.

The end portions of each of the sealing layers SE11 and SE12 and the end portions of each of the stacked films FL1 and FL2 are located on the partition 6. In the example of FIG. 5, the stacked film FL1 and the first sealing layer SE11 located above the partition 6 between the subpixels SP1 and SP2 are spaced apart from the stacked film FL2 and the first sealing layer SE12 located above this partition 6.

The partition 6 and the first sealing layers SE11 and SE12 are covered with an organic insulating layer RS1 (a first organic insulating layer). The organic insulating layer RS1 is covered with a second sealing layer SE2. The second sealing layer SE2 is covered with an organic insulating layer RS2 (a second organic insulating layer). In the illustrated example, the organic insulating layer RS2 is thicker than the organic insulating layer RS1.

The lenses ML1 and ML2 are provided on the organic insulating layer RS2. The lenses ML1 and ML2 each have a convex shape projecting toward the side opposite to the substrate 10 in the Z direction. The lens ML1 overlaps the lower electrodes LE11 and LE12, the stacked film FL1, and the first sealing layer SE11 in the Z direction. The lens ML2 overlaps the lower electrodes LE21 and LE22, the stacked film FL2, and the first sealing layer SE12 in the Z direction. As an example, the lenses ML1 and ML2 are covered with an air layer. As another example, the lenses ML1 and ML2 each are covered with a material that has the refractive index smaller than that of each of the lenses ML1 and ML2.

The center line MC1 is provided on the thickest portion of the lens ML1. Though not illustrated in FIG. 5, the center line MC2 shown in FIG. 4 is provided on the thickest portion of the lens ML2.

A focus of each of the lenses ML1 and ML2 is preferably coincident with the position of the light emitting layers included in the organic layers OR1 and OR2. The position of the focus of each of the lenses ML1 and ML2 can be coincident with the position of the light emitting layers, for example, by varying the thicknesses of the organic insulating layers RS1 and RS2.

A cover member such as a polarizer and a cover glass may further be provided above the lenses ML1 and ML2.

The display device DSP further comprises a light-shielding layer BM provided on the organic insulating layer RS2. The light-shielding layer BM covers a portion between the lenses ML1 and ML2 in the X direction. In the illustrated example, the light-shielding layer BM overlaps lens edges ME1 to ME4. Both end portions of the light-shielding layer BM are covered with the lenses ML1 and ML2.

Each of the inorganic insulating layer 5, the first sealing layers SE11 and SE12, and the second sealing layer SE2 is formed of, for example, an inorganic insulating material such as silicon nitride (SiNx), silicon oxide (SiOx), silicon oxynitride (SiON), or aluminum oxide (Al₂O₃). Each of the organic insulating layers RS1 and RS2 is formed of, for example, a resinous material (an organic insulating material) such as epoxy resin or acrylic resin.

The lower portion 61 of the partition 6 is formed of a conductive material and is electrically connected to the upper electrodes UE1 and UE2. The first conductive layer 63 is formed of, for example, titanium-based material such as titanium and titanium compound. The second conductive layer 64 is formed of a material that is different from each of the first conductive layer 63 and the upper portion 62. For example, the second conductive layer 64 is formed of aluminum-based material such as aluminum and aluminum compound.

The upper portion 62 of the partition 6 is formed of, for example, a conductive material. However, the upper portion 62 may be formed of an insulating material. The thin film 65 is, formed of, for example, titanium-based material such as titanium and titanium compound. The thin film 66 is formed of, for example, oxide conductive material such as indium tin oxide (ITO).

Each of the lower electrodes LE11, LE12, LE21, and LE22 is a multilayer body including a transparent layer formed of an oxide conductive material such as indium tin oxide (ITO) and a reflective layer formed of a metal material such as silver. For example, each of the lower electrodes LE11, LE12, LE21, and LE22 is a multilayer body including the reflective layer between a pair of transparent layers. The transparent layer of the lower layer functions as a close-contact layer in close contact with the insulating layer 12.

As an example, the organic layer OR1 includes a light emitting layer formed of a material emitting light in a green color, and the organic layer OR2 includes a light emitting layer formed of a material emitting light in a blue color. As another example, the organic layer OR1 includes a light emitting layer formed of a material emitting light in a blue color, and the organic layer OR2 includes a light emitting layer formed of a material emitting light in a green color. Each of the organic layers OR1 and OR2 includes a plurality of functional layers such as a hole injection layer, a hole transport layer, an electron blocking layer, a hole blocking layer, an electron transport layer, and an electron injection layer.

The upper electrodes UE1 and UE2 are formed of, for example, a metal material such as an alloy of magnesium and silver (MgAg). Each of the cap layers CP1 and CP2 is a multilayer body consisting of a plurality of thin films. All of the thin films are transparent and have refractive indexes different from each other.

The lenses ML1 and ML2 are formed of, for example, a transparent resinous material such as epoxy resin, acrylic resin, and polyimide resin.

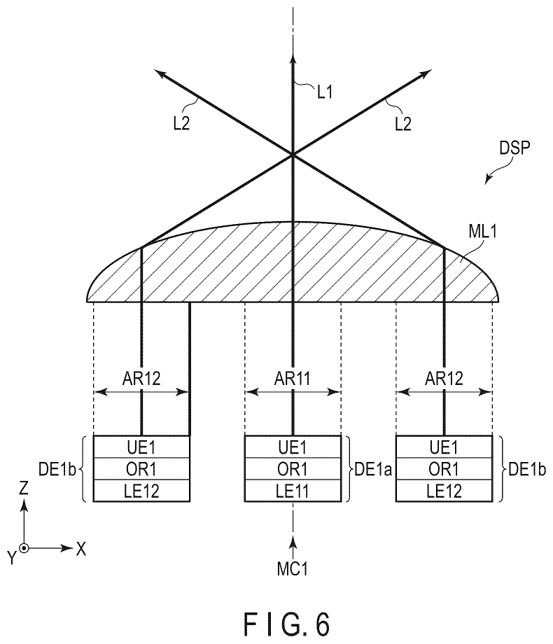

FIG. 6 is a view for explaining the function of the lens ML1 shown in FIG. 5. Light beam L1 emitted along the Z direction from the display element DE1a overlapping the center line MC1 is hardly refracted at the interface between the lens ML1 and air and travels along the Z direction. In contrast, light beam L2 emitted along the Z direction from the display element DE1b is refracted at the interface between the lens ML1 and air and travels along a direction tilted from the Z direction to the center line MC1 side of the lens ML1.

That is, a user in the traveling direction side of the light beam L1 can visually-recognize light beams emitted from the display element DE1a but hardly visually-recognizes light beams emitted from the display element DE1b. A user in the traveling direction side of the light beam L2 can visually-recognize light beams emitted from the display element DE1b but hardly visually-recognizes light beams emitted from the display element DE1a. In this manner, the lens ML1 has the function of refracting light beams emitted from the display elements and thus limiting the viewing angles.

In the display device DSP in the first mode, the display element DE1a emits light, but the display element DE1b does not emit light. Therefore, a user in the traveling direction side of the light beam L1 can sufficiently visually-recognize an image displayed in the display device DSP, but a user in the traveling direction side of the light beam L2 hardly visually-recognizes the image. That is, the first mode limits the viewing angle of the display device DSP.

In contrast, in the display device DSP in the second mode, the display elements DE1a and DE1b both emit light. Therefore, users in the traveling direction side of both of the light beam L1 and the light beam L2 can sufficiently visually-recognize the image. That is, the second mode has a broader viewing angle of the display device DSP than that of the first mode. Therefore, switching between the first mode and the second mode can control the viewing angle of the display device DSP.

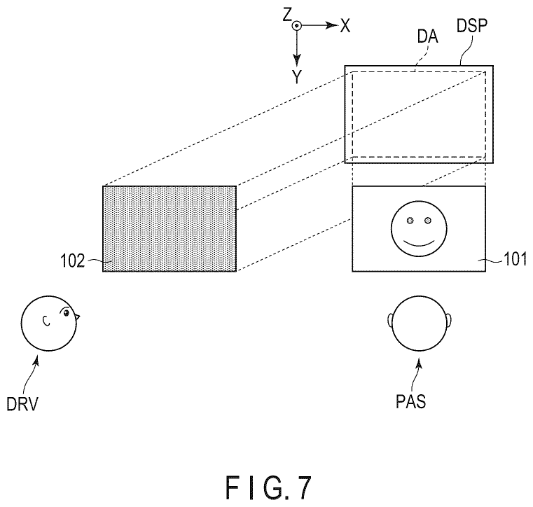

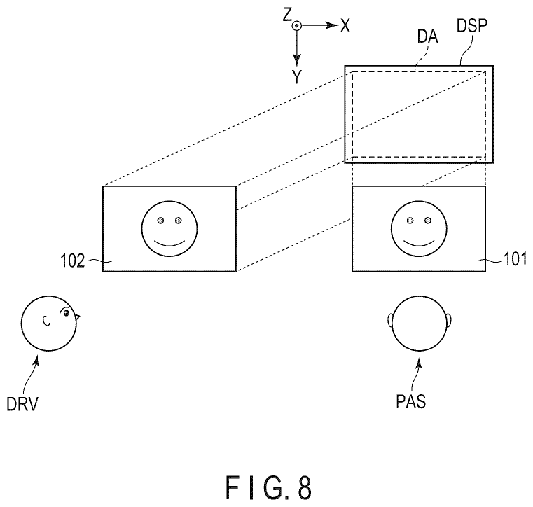

Next, the following describes a case where the display device DSP of the present embodiment is mounted on a vehicle such as an automobile. FIG. 7 is a view showing a state where the display device DSP mounted on a vehicle-mounted device displays an image in the first mode. FIG. 8 is a view showing a state where the display device DSP mounted on a vehicle-mounted device displays an image in the second mode. As an example, the following describes a case where the display device DSP is located in front of the passenger seat.

As shown in FIG. 7, when an image is displayed in the first mode, a passenger PAS in the passenger seat can sufficiently visually-recognize a screen 101, on which this image is displayed in the display area DA. In contrast, the visual recognition of the displayed image is restricted for a driver DRV. The driver DRV can visually-recognize a screen 102 on which a darker image, compared with the one which can be seen from the passenger seat side, or on which no image is displayed.

As shown in FIG. 8, when an image is displayed in the second mode, the passenger PAS in the passenger seat can sufficiently visually-recognize the screen 101, on which an image is displayed in the display area DA. The driver DRV can sufficiently visually-recognize a screen 102 on which the same image as the image visually-recognized by the passenger PAS in the passenger seat is displayed.

At the time of driving, an image is displayed in the first mode when the following case is required: an image displayed in the display device DSP is hardly visually-recognizable from the side of the driver seat and, in contrast, this image is visually-recognizable from a passenger seat. Thus, as shown in FIG. 7, the visual recognition of an image is limited from the side of the driver seat. In contrast, the image is sufficiently visually-recognizable from the side of the passenger seat. In contrast, an image is displayed in the second mode when the following case is required: an image is visually-recognizable from both of the side of the driver seat and the side of the passenger seat while engine is in off state. Thus, as shown in FIG. 8, an image is sufficiently visually-recognizable from both of the side of the driver seat and the side of the passenger seat. Switching between the first mode and the second mode in this manner can control the viewing angle, switching the visibility of an image from, particularly, the side of the driver seat.

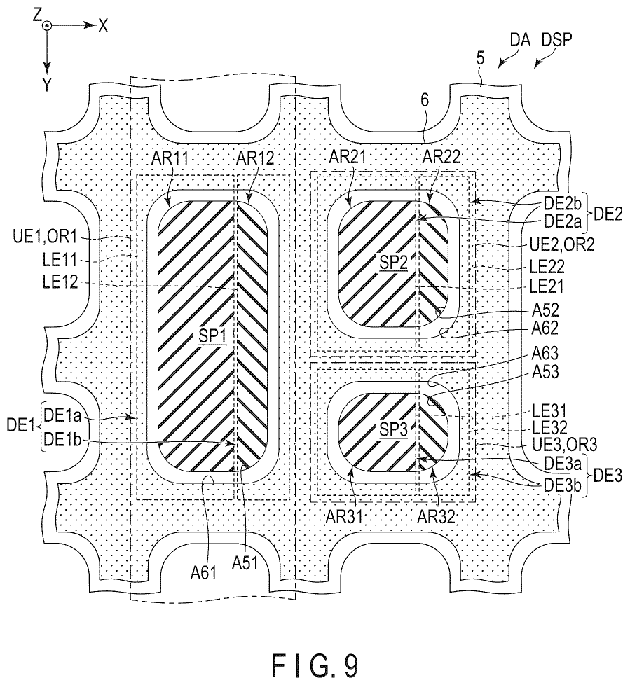

FIG. 9 is a schematic plan view showing another example of the layout of the subpixels SP1, SP2, and SP3. In the example of FIG. 9, the lower electrodes LE11 and LE12 are arranged along the X direction, the lower electrodes LE21 and LE22 are arranged along the X direction, and the lower electrodes LE31 and LE32 are arranged along the X direction. The first area AR11 is greater than the second area AR12. The first area AR21 is greater than the second area AR22. The first area AR31 is greater than the second area AR32.

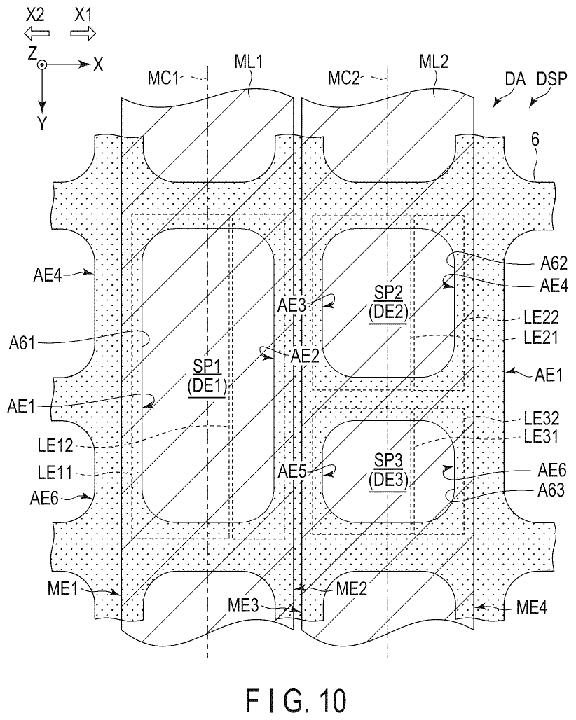

FIG. 10 is a plan view showing an example of the layout of the partition 6 and the lenses ML1 and ML2 shown in FIG. 9. In the example shown in FIG. 10, the direction in which the lower electrodes LE11 and LE12 are arranged (the X direction) is orthogonal to the center line MC1 of the lens ML1. In addition, the direction in which the lower electrodes LE21 and LE22 are arranged and the direction in which the lower electrodes LE31 and LE32 are arranged (the X direction) each are orthogonal to the center line MC2 of the lens ML2.

In the example shown in FIG. 10, the center line MC1 of the lens ML1 overlaps the lower electrode LE11 in plan view. In addition, the center line MC2 of the lens ML2 overlaps the lower electrodes LE21 and LE31 in plan view.

In the example shown in FIG. 10, the aperture edge AE1 overlaps the lower electrode LE11 in plan view, and the aperture edge AE2 overlaps the lower electrode LE12 in plan view. In addition, the aperture edge AE3 overlaps the lower electrode LE21 in plan view, and the aperture edge AE4 overlaps the lower electrode LE22 in plan view. Further, the aperture edge AE5 overlaps the lower electrode 31 in plan view, and the aperture edge AE6 overlaps the lower electrode 32 in plan view.

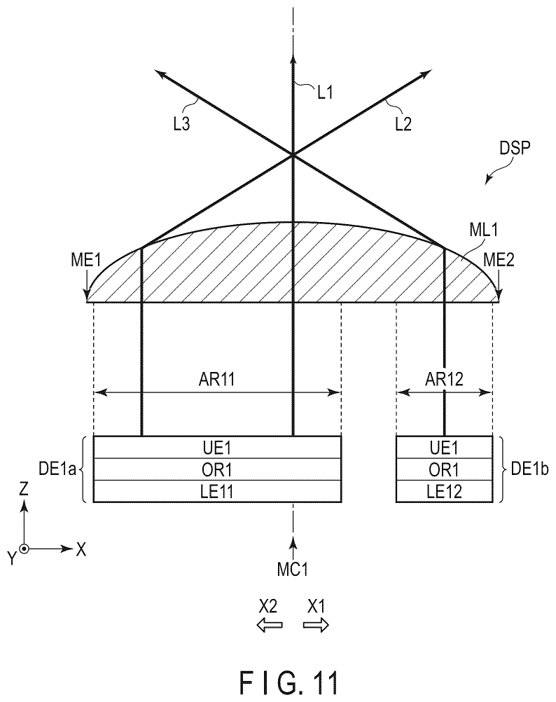

FIG. 11 is a view for explaining the function of the lens ML1 shown in FIG. 10. A direction from the lens edge ME1 to the center line MC1 along the X direction is hereinafter referred to as a direction X1. A direction from the lens edge ME2 to the center line MC1 along the first direction X is hereinafter referred to as a direction X2.

The Light beam L1 emitted along the Z direction from a portion overlapping the center line MC1 of the display element DE1a is hardly refracted at the interface between the lens ML1 and air and travels along the Z direction. The light beam L2 emitted along the Z direction from a portion close to the direction X2 side with respect to the center line MC1 of the display element DE1a is refracted at the interface between the lens ML1 and air and travels along a direction tilted from the Z direction to the center line MC1 side (the direction X1 side) of the lens ML1. The light beam L3 emitted along the Z direction from the display element DE1b is refracted at the interface between the lens ML1 and air and travels along a direction tilted from the Z direction to the center line MC1 side (the direction X2 side) of the lens ML1.

That is, users in the traveling direction side of both of the light beam L1 and the light beam L2 can visually-recognize light beams emitted from the display element DE1a but hardly visually-recognize light beams emitted from the display element DE1b. That is, a user in the traveling direction side of the light beam L3 can visually-recognize light beams emitted from the display element DE1b but hardly visually-recognizes light beams emitted from the display elements DE1a.

When the display device DSP is in the first mode, users in the traveling direction side of both of the light beam L1 and the light beam L2 can sufficiently visually-recognize the image displayed in the display device DSP. When the display device DSP is in the second mode, users in the traveling direction side of all of the light beams L1, L2, and L3 can sufficiently visually-recognize the image. Therefore, switching between the first mode and the second mode can control the viewing angle of the display device DSP.

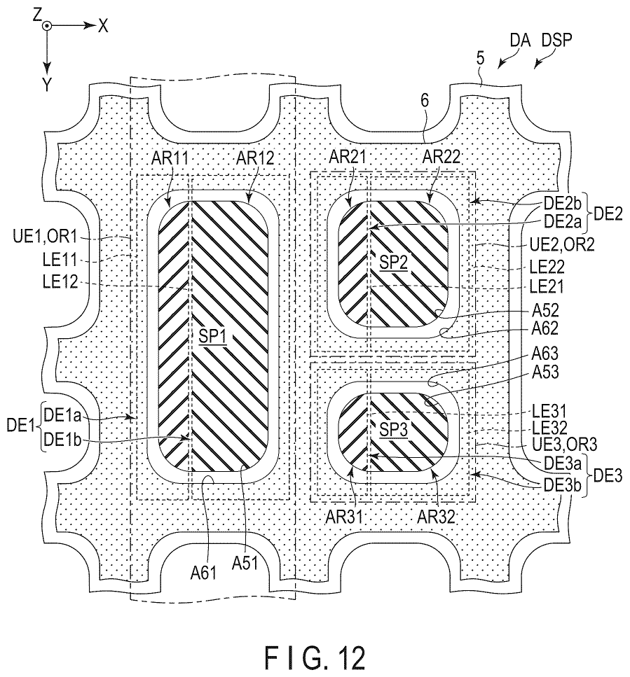

FIG. 12 is a schematic plan view showing another example of the layout of the subpixels SP1, SP2, and SP3. In the example of FIG. 12, the first area AR11 is smaller than the second area AR12, the first area AR21 is smaller than the second area AR22, and the first area AR31 is smaller than the second area AR32.

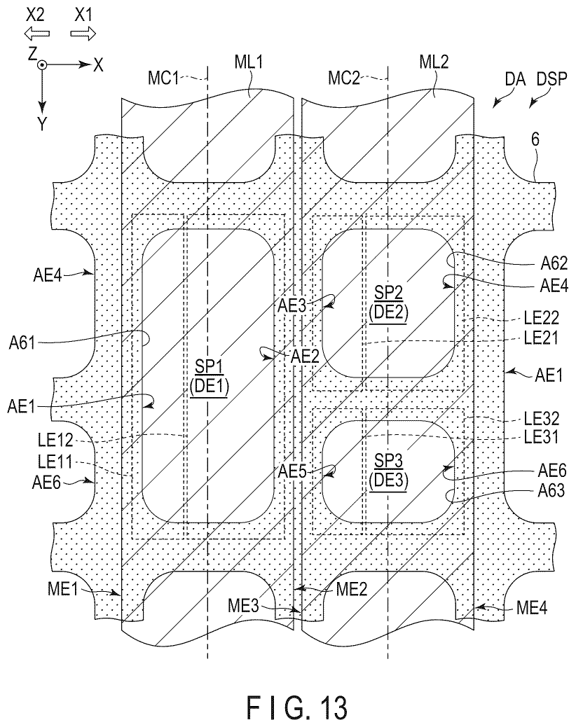

FIG. 13 is a plan view showing an example of the layout of the partition 6 and the lenses shown in FIG. 12. In the example shown in FIG. 13, the center line MC1 of the lens ML1 overlaps the lower electrode LE12 in plan view. In addition, the center line MC2 of the lens ML2 overlaps the lower electrodes LE22 and LE32 in plan view.

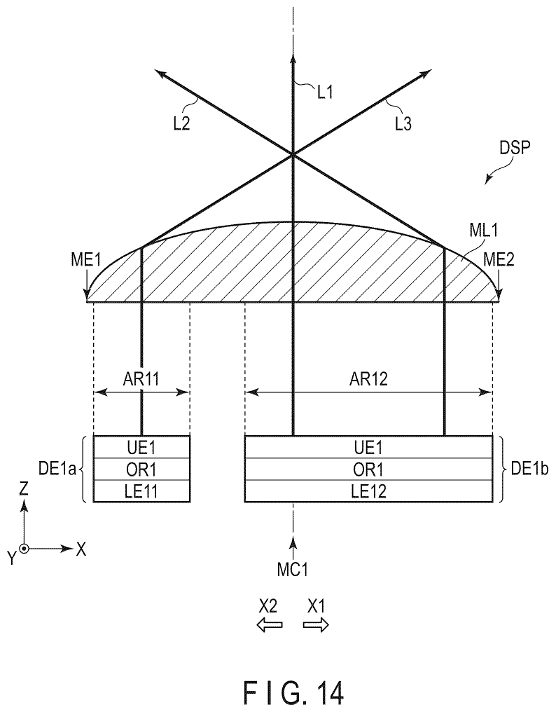

FIG. 14 is a view for explaining the function of the lens ML1 shown in FIG. 13. The light beam L1 emitted along the Z direction from a portion overlapping the center line MC1 of the display element DE1b is hardly refracted at the interface between the lens ML1 and air and travels along the Z direction. The light beam L2 emitted along the Z direction from a portion close to the direction X1 side with respect to the center line MC1 of the display element DE1b is refracted at the interface between the lens ML1 and air and travels along a direction tilted from the Z direction to the center line MC1 side (the direction X2 side) of the lens ML1. The light beam L3 emitted along the Z direction from the display element DE1a is refracted at the interface between the lens ML1 and air and travels along a direction tilted from the Z direction to the center line MC1 side (the direction X1 side) of the lens ML1.

That is, users in the traveling direction side of both of the light beams L1 and L2 can visually-recognize light beams emitted from the display element DE1b but hardly visually-recognize light beams emitted from the display element DE1a. That is, a user in the traveling direction side of the light beam L3 can visually-recognize light beams emitted from the display element DE1a but hardly visually-recognizes light beams emitted from the display element DE1b.

When the display device DSP is in the first mode, a user in the traveling direction side of the light beam L3 can sufficiently visually-recognize the image displayed in the display device DSP. When the display device DSP is in the second mode, users in the traveling direction side of all of the light beams L1, L2, and L3 can sufficiently visually-recognize the image. Therefore, switching between the first mode and the second mode can control the viewing angle of the display device DSP.

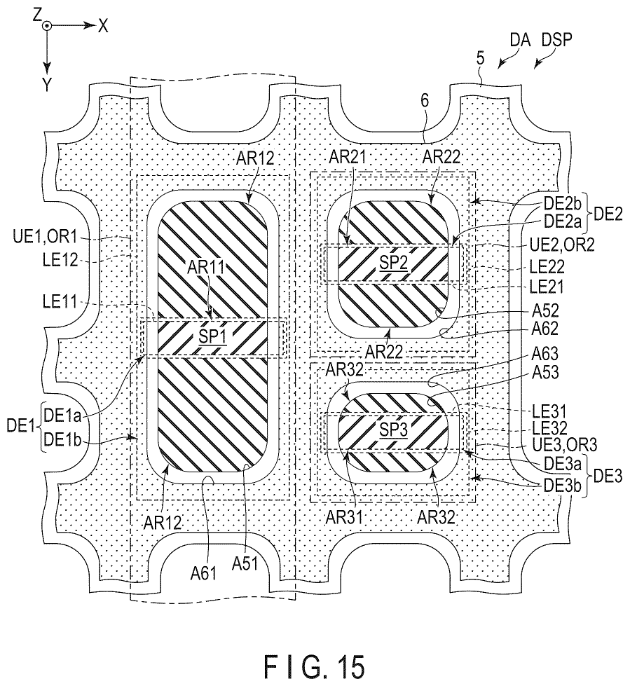

FIG. 15 is a schematic plan view showing another example of the layout of the subpixels SP1, SP2, and SP3. In the example shown in FIG. 15, each of the lower electrodes LE11, LE21, and LE31 has a rectangular shape having long sides parallel to the X direction. Further, short sides parallel to the Y direction of each of the lower electrodes LE11, LE21, and LE31 overlap the inorganic insulating layer 5 and the partition 6 in plan view.

In the example shown in FIG. 15, the lower electrode LE11 is surrounded by the lower electrode LE12 in plan view, the lower electrode LE21 is surrounded by the lower electrode LE22 in plan view, and the lower electrode LE31 is surrounded by the lower electrode LE32 in plan view.

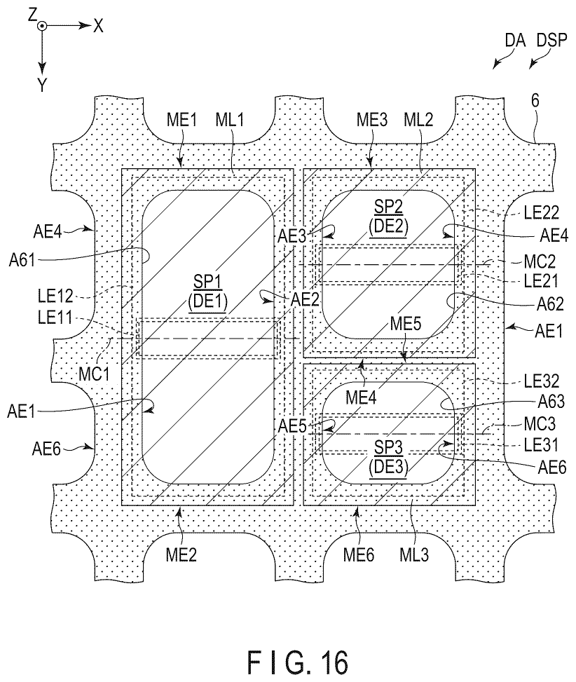

FIG. 16 is a plan view showing an example of the layout of the partition 6 and the lenses ML1, ML2, and ML3 shown in FIG. 15. In the example shown in FIG. 16, the lenses ML1 and ML2 extend in the X direction. The lens edges ME1 to ME4 and the center lines MC1 and MC2 are parallel to the X direction. The lens ML1 covers the aperture A61, and the lens ML2 covers the aperture A62. In the example show in FIG. 16, a cross-sectional shape along the Y direction of each of the lenses ML1 and ML2 is a convex shape projecting toward the side opposite to the substrate 10 (refer to FIG. 5).

In addition to the lenses ML1 and ML2, the display device DSP further comprises a lens ML3. In the example shown in FIG. 15, the lens ML3 extends in the X direction. The lens ML3 overlaps the aperture A63 and the display element DE3 in plan view. In the example of FIG. 15, the lens ML3 covers the aperture A63.

The lens ML3 includes a lens edge ME5 (a first lens edge), a lens edge ME6 (a second lens edge), and a center line MC3. The lens edges ME5 and ME6 and the center line MC3 are parallel to the X direction. In the illustrated example, each of the lens edges ME5 and ME6 overlaps the partition 6 in plan view. The center line MC3 overlaps the aperture A63 and the display element DE3 in plan view. The center line MC3 overlaps the lower electrode LE31 as well in plan view. In the example show in FIG. 16, the cross-sectional shape along the Y direction of the lens ML3 is a convex shape projecting toward the side opposite to the substrate 10.

Thus, in the display device DSP shown in FIG. 16, switching between the first mode and the second mode can control the viewing angle in the Y direction. For example, in a case where the display device DSP is mounted on an automobile, this control of the viewing angle in the Y direction can suppress a reflection of a display image on a windshield of the automobile.

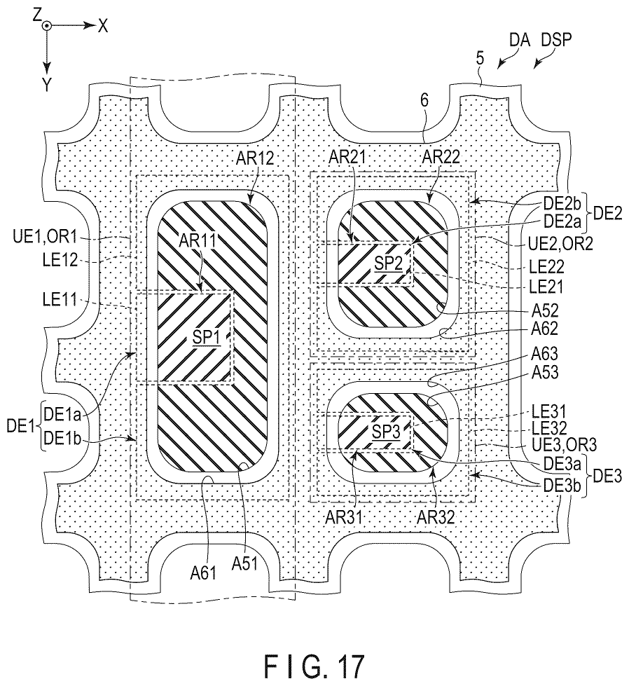

FIG. 17 is a schematic plan view showing another example of the layout of the subpixels SP1, SP2, and SP3. In the example shown in FIG. 17, the lower electrodes LE11 and LE12 are arranged in the X direction and the Y direction, the lower electrodes LE21 and LE22 are arranged in the X direction and the Y direction, and the lower electrodes LE31 and LE32 are arranged in the X direction and the Y direction. The lower electrode LE12 is formed in an approximately U-shape along the outer shape of the lower electrode LE11. The lower electrode LE22 is formed in an approximately U-shape along the outer shape of the lower electrode LE21. The lower electrode LE32 is formed in an approximately U-shape along the outer shape of the lower electrode LE31.

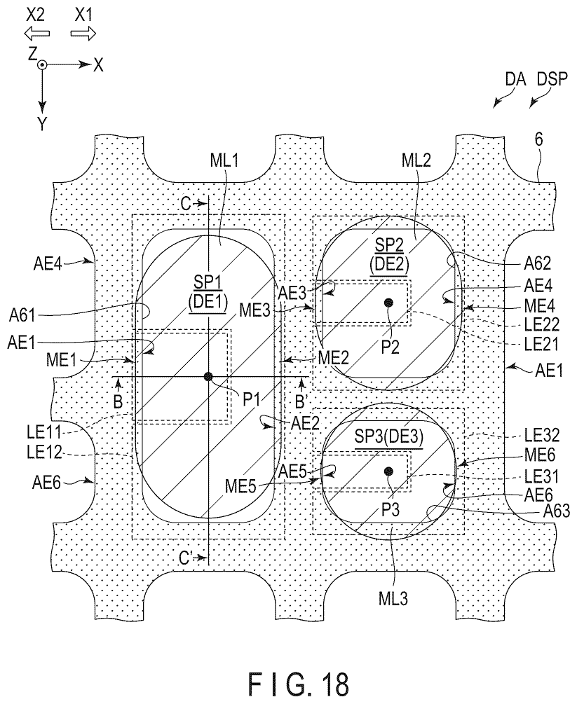

FIG. 18 is a plan view showing an example of the layout of the partition 6 and the lenses ML1, ML2, and ML3 shown in FIG. 17. In the example shown in FIG. 18, in plan view, the lens ML1 is formed to have a shape constituted by the lens edges ME1 and ME2, which are parallel to the Y direction and two semicircular arcs outwardly extending outside of the lens ML1 in the Y direction. In the illustrated example, in plan view, the lens ML2 is formed to have a shape constituted by the lens edges ME3 and ME4, which are parallel to the Y direction and two semicircular arcs outwardly extending outside of the lens ML2 in the Y direction. The lenses ML1 and ML2 may have an elliptic shape or a circular shape in plan view.

In the example shown in FIG. 18, the lens ML3 has a circular shape in plan view. The lens ML3 may have a shape constituted by a straight line parallel to the X direction and two semicircular arcs outwardly extending outside of the lens ML3 in the X direction. Alternatively, the lens ML3 may have an elliptic shape.

In the example shown in FIG. 18, the lenses ML1, ML2, and ML3 do not completely cover the respective apertures A61, A62, and A63 in plan view. The lenses ML1, ML2, and ML3 may completely cover the respective apertures A61, A62, and A63 in plan view. Of the apertures A61, A62, and A63, portions that do not overlap the lenses ML1, ML2, and ML3 overlap a light-shielding layer that is not shown (the light-shielding layer BM shown in FIG. 5).

The lenses ML1, ML2, and ML3 has respective principal points P1, P2, and P3. The principal point P1 overlaps the lower electrode LE11 in plan view. The principal point P2 overlaps the lower electrode LE21 in plan view. The principal point P3 overlaps the lower electrode LE31 in plan view. The principal points P1, P2, and P3 are provided on the thickest portion of the respective lenses ML1, ML2, and ML3.

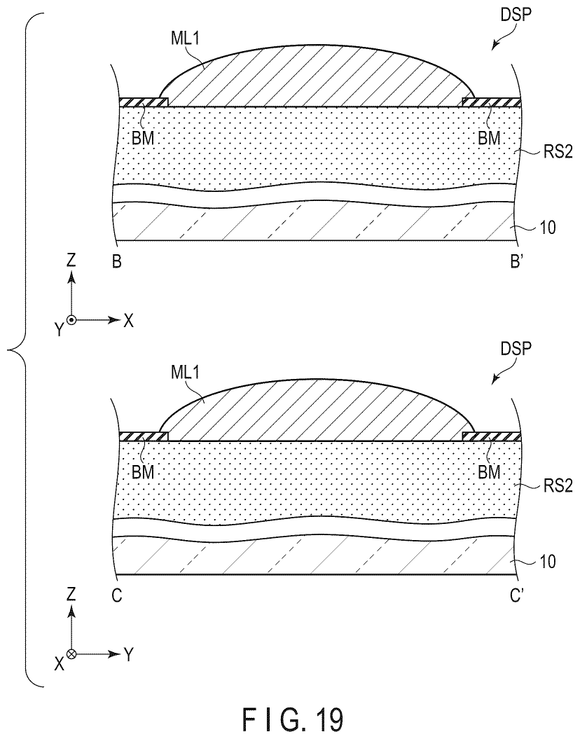

FIG. 19 is a cross-sectional view showing the configuration example of the display device DSP along line B-B′ and line C-C′ in FIG. 18. The upper half of FIG. 19 is a cross-sectional view showing the configuration example of the display device DSP along line B-B′ in FIG. 18. The cross-sectional shape along the X direction of the lens ML1 is a convex shape projecting toward the side opposite to the substrate 10. Thus, as described above, the viewing angle in the X direction can be limited.

The lower half of FIG. 19 is a cross-sectional view showing the configuration example of the display device DSP along line C-C′ in FIG. 18. The cross-sectional shape along the Y direction of the lens ML1 is a convex shape projecting toward the side opposite to the substrate 10. Thus, similarly to that in the X direction, the viewing angle in the Y direction can be limited as well. For example, in a case where the display device DSP is mounted on an automobile, this control of the viewing angle in the Y direction can suppress a reflection of a display image on a windshield of the automobile.

FIG. 19 omits the illustration of the portions located between the organic insulating layer RS2 and the substrate 10. Each of the above described configurations can be adopted between the organic insulating layer RS2 and the substrate 10.

Similarly to that of the lens ML1, the cross-sectional shape along the X direction and Y direction of each of the lenses ML2 and ML3 is a convex shape projecting toward the side opposite to the substrate 10.

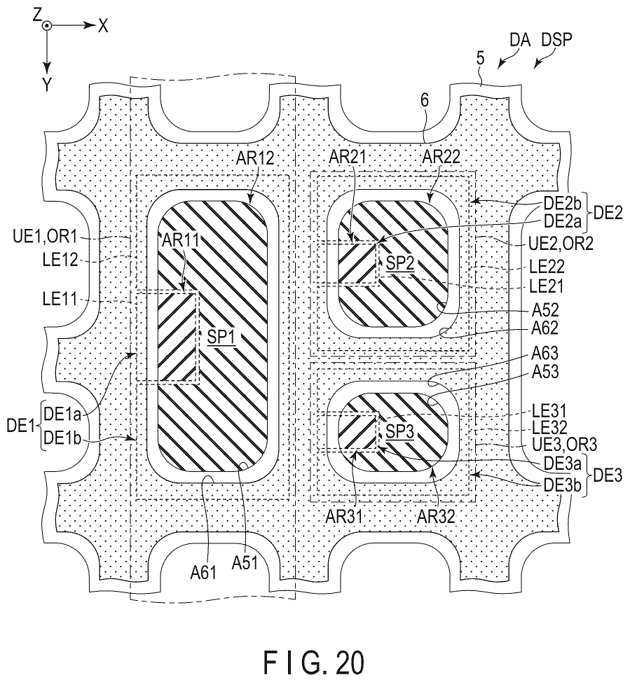

FIG. 20 is a schematic plan view showing another example of the layout of the subpixels SP1, SP2, and SP3. The area of the first area AR11 that is shown in FIG. 20 is smaller than the area of the first area AR11 that is shown in FIG. 17. The first area AR21 that is shown in FIG. 20 is smaller than the area of the first area AR21 that is shown in FIG. 17. The first area AR31 that is shown in FIG. 20 is smaller than the area of the first area AR31 that is shown in FIG. 17.

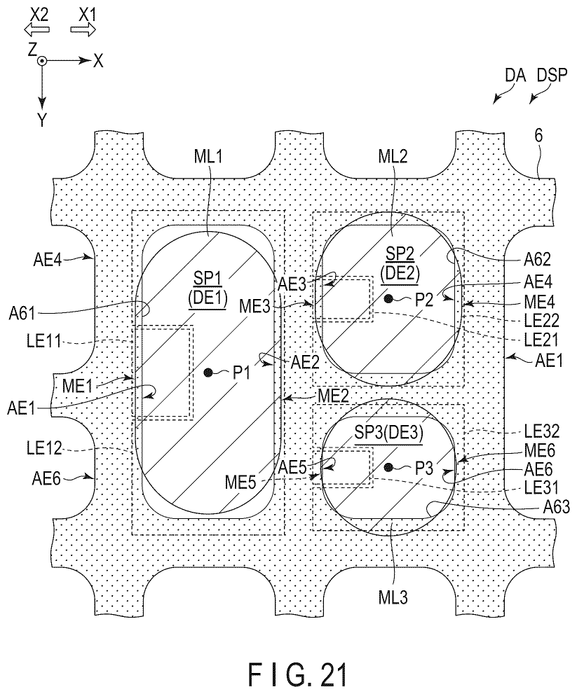

FIG. 21 is a plan view showing an example of the layout of the partition 6 and the lenses ML1, ML2, and ML3 shown in FIG. 20. In the example shown in FIG. 21, the principal point P1 overlaps the lower electrode LE12 in plan view, the principal point P2 overlaps the lower electrode LE22 in plan view, and the principal point P3 overlaps the lower electrode LE32 in plan view. Thus, the display device DSP shown in FIG. 21 has the limited viewing angle in the X direction and the Y direction.

In FIG. 17 to FIG. 21, when the X direction corresponds to the first direction, the Y direction corresponds to the second direction. In contrast, when the Y direction corresponds to the first direction, the X direction corresponds to the second direction.

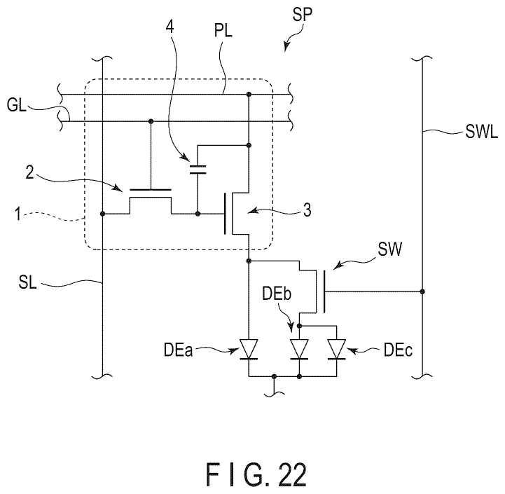

FIG. 22 is a circuit diagram showing another example of the circuit configuration of the subpixel SP. In addition to the display elements DEa and DEb, the subpixel SP further comprises a display element DEc driven by the pixel circuit 1. The display element DEc is parallely connected to the display element DEb. The anode of each of the display elements DEb and DEc is connected to the source electrode or the drain electrode of the switching element SW. Similarly to the display elements DEa and DEb, the display element DEc is an organic light-emitting diode (OLED) serving as a light emitting element.

When the circuit is the one shown in FIG. 22, the first mode has the off-state switching element SW. Thus, the first mode has the conductivity between the drive transistor 3 and the display element DEa but does not have the conductivity between the drive transistor 3 and the display element DEb and the conductivity between the drive transistor 3 and the display element DEc. Thus, in the first mode, the display element DEa emits light but the display elements DEb and DEc do not emit light.

The second mode has the on-state switching element SW. Thus, the second mode has the conductivity between the drive transistor 3 and the display element DEa, the conductivity between the drive transistor 3 and the display element DEb, and the conductivity between the drive transistor 3 and the display element DEc. Thus, in the second mode, all of the display elements DEa, DEb, and DEc emit light.

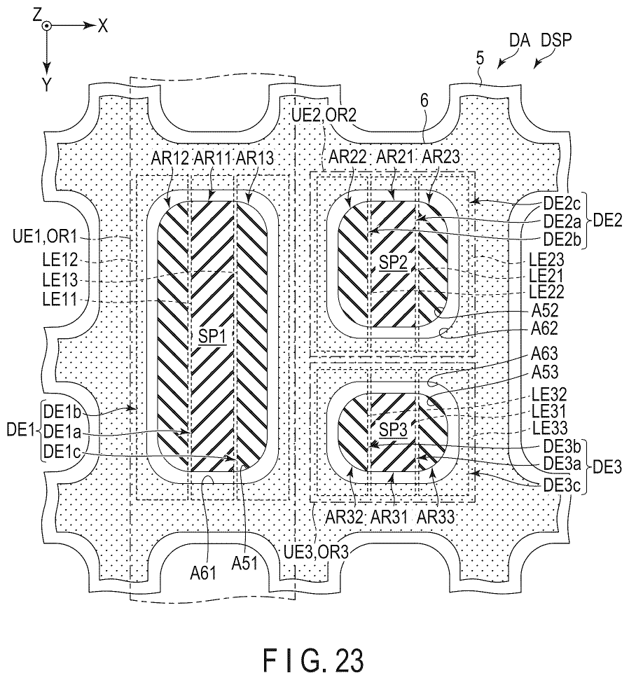

FIG. 23 is a schematic plan view showing another example of the layout of the subpixels SP1, SP2, and SP3. In addition to the display elements DE1a and DE1b, the display element DE1 of the subpixel SP1 further includes the display element DE1c. The display element DE1c includes a lower electrode LE13, the upper electrode UE1, and the organic layer OR1. The upper electrode UE1 and the organic layer OR1 continuously overlap the lower electrodes LE11, LE12, and LE13.

The lower electrode LE13 is spaced apart from the lower electrodes LE11 and LE12. The lower electrode LE13 overlaps the apertures A51 and A61. The lower electrode LE11 is provided between the lower electrodes LE12 and LE13 in the X direction.

In addition to the display elements DE2a and DE2b, the display element DE2 of the subpixel SP2 further includes a display element DE2c. The display element DE2c includes a lower electrode LE23, the upper electrode UE2, and the organic layer OR2. The upper electrode UE2 and the organic layer OR2 continuously overlap the lower electrodes LE21, LE22, and LE23.

The lower electrode LE23 is spaced apart from the lower electrodes LE21 and LE22. The lower electrode LE23 overlaps the apertures A52 and A62. The lower electrode LE21 is provided between the lower electrodes LE22 and LE23 in the X direction.

In addition to the display elements DE3a and DE3b, the display element DE3 of the subpixel SP3 further includes a display element DE3c. The display element DE3c includes a lower electrode LE33, the upper electrode UE3, and the organic layer OR3. The upper electrode UE3 and the organic layer OR3 continuously overlap the lower electrodes LE31, LE32, and LE33.

The lower electrode LE33 is spaced apart from the lower electrodes LE31 and LE32. The lower electrode LE33 overlaps the apertures A53 and A63. The lower electrode LE31 is provided between the lower electrodes LE32 and LE33 in the X direction.

The display elements DE1c, DE2c, and DE3c each correspond to the display element DEc shown in FIG. 22. For example, the lower electrode LE13 corresponds to the anode of the display element DE1c, the lower electrode LE23 corresponds to the anode of the display element DE2c, and the lower electrode LE33 corresponds to the anode of the display element DE3c. The lower electrodes LE13, LE23, and LE33 each are connected to the source electrode or the drain electrode of the switching element SW in each subpixel SP shown in FIG. 22. That is, the lower electrode LE12 and the lower electrode LE13 are electrically connected to each other, the lower electrode LE22 and the lower electrode LE23 are electrically connected to each other, and the lower electrode LE32 and the lower electrode LE33 are electrically connected to each other. In the example of FIG. 23, the outer shapes of the lower electrodes LE13, LE23, and LE33 are indicated by the dotted lines.

In addition to the first area AR11 and the second area AR12, the organic layer OR1 further includes a third area AR13 corresponding to the area where the aperture A51 and the lower electrode LE13 overlap each other in plan view. In addition to the first area AR21 and the second area AR22, the organic layer OR2 further includes a third area AR23 corresponding to the area where the aperture A52 and the lower electrode LE23 overlap each other in plan view. In addition to the first area AR31 and the second area AR32, the organic layer OR3 further includes a third area AR33 corresponding to the area where the aperture A53 and the lower electrode LE33 overlap each other in plan view. In the example of FIG. 23, the third areas AR13, AR23, and AR33 are indicated by hatch lines.

As described above, in the display device DSP in the first mode, the display element DEa emits light, but the display elements DEb and DEc do not emit light, these display elements being shown in FIG. 22. Thus, in the first mode, the first areas AR11, AR21, and AR31 emit light, but the second areas AR12, AR22, and AR32 and the third areas AR13, AR23, and AR33 do not emit light.

As described above, in the display device DSP in the second mode, the display elements DEa, DEb, and DEc all emit light, these elements being shown in FIG. 22. Thus, in the second mode, all of the first areas AR11, AR21, and AR31, the second areas AR12, AR22, and AR32, and the third areas AR13, AR23, and AR33 emit light.

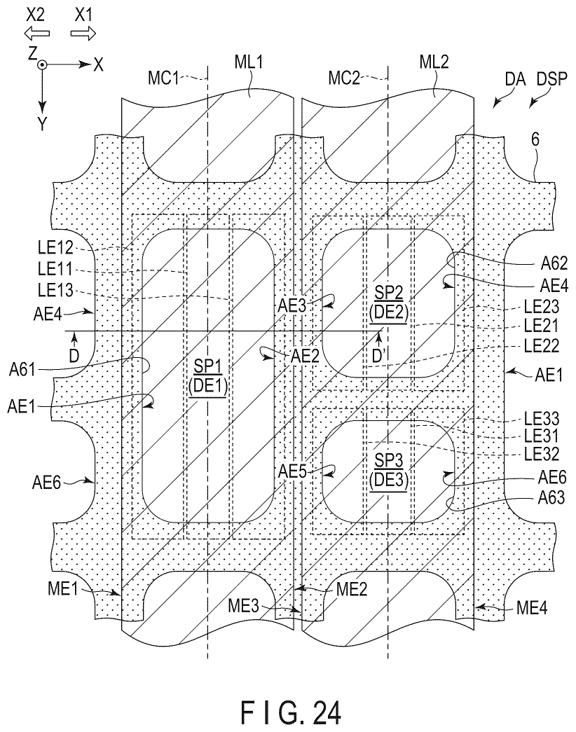

FIG. 24 is a plan view showing an example of the layout of the partition 6 and the lenses ML1 and ML2 shown in FIG. 23. In the example shown in FIG. 24, the aperture edge AE1 overlaps the lower electrode LE12 in plan view, and the aperture edge AE2 overlaps the lower electrode LE13 in plan view. The aperture edge AE3 overlaps the lower electrode LE22 in plan view, and the aperture edge AE4 overlaps the lower electrode LE23. The aperture edge AE5 overlaps the lower electrode LE32 in plan view, and the aperture edge AE6 overlaps the lower electrode LE33.

In the example shown in FIG. 24, the center line MC1 is located between the lower electrodes LE12 and LE13 in the X direction and overlaps the lower electrode LE11 in plan view. Further, the center line MC2 is located between the lower electrodes LE22 and LE23 and between the lower electrodes LE32 and LE33 in the X direction and overlaps the lower electrodes LE21 and LE31 in plan view.

In the example shown in FIG. 24, the direction in which the lower electrodes LE11, LE12, and LE13 are arranged (the X direction) is orthogonal to the center line MC1 of the lens ML1. In addition, the direction in which the lower electrodes LE21, LE22, and LE33 are arranged and the direction in which the lower electrodes LE31, LE32, and LE33 (the X direction) are arranged each are orthogonal to the center line MC2 of the lens ML2.

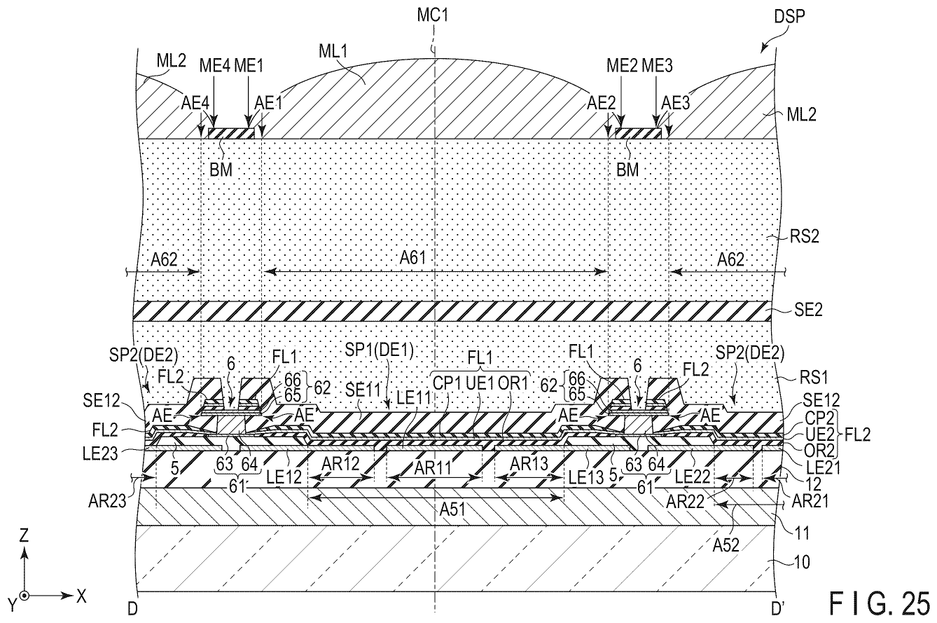

FIG. 25 is a cross-sectional view showing the configuration example of the display device along line D-D′ in FIG. 24. The lower electrode LE13 is provided on the insulating layer 12. The organic layer OR1 is in contact with the lower electrode LE13 through the aperture A51. The area where the organic layer OR1 and the lower electrode LE13 are in contact with each other corresponds to the third area AR13. The organic layer OR1 is in contact with the insulating layer 12 through the aperture A51 between the lower electrodes LE11 and LE13 and between the lower electrodes LE12 and LE13.

In the above example, the lower electrodes LE11, LE21, and LE31 each correspond to the first lower electrode, the lower electrodes LE12, LE22, and LE32 each correspond to the second lower electrode, and the lower electrodes LE13, LE23, and LE33 each correspond to the third electrode.

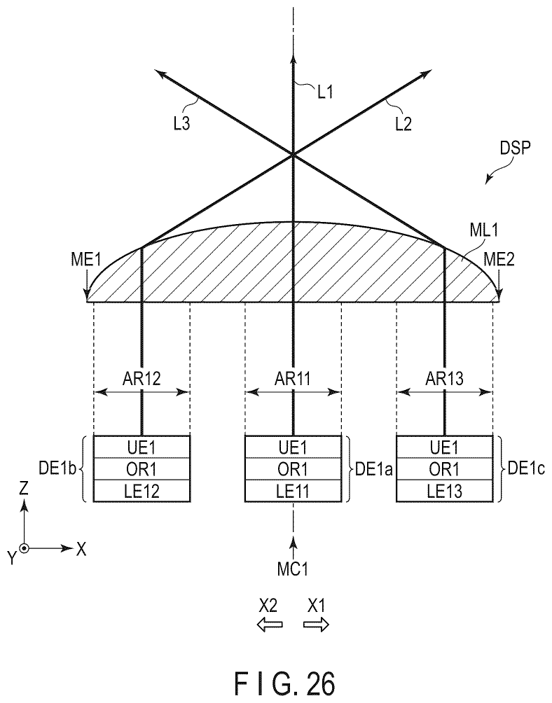

FIG. 26 is a view for explaining the function of the lens ML1 shown in FIG. 25. The light beam L1 emitted along the Z direction from the display element DE1a is hardly refracted at the interface between the lens ML1 and air and travels along the Z direction. The light beam L2 emitted along the Z direction from the display element DE1b is refracted at the interface between the lens ML1 and air and travels along a direction tilted from the Z direction to the center line MC1 side (the direction X1 side) of the lens ML1. The light beam L3 emitted along the Z direction from the display element DE1c is refracted at the interface between the lens ML1 and air and travels along a direction tilted from the Z direction to the center line MC1 side (the direction X2 side) of the lens ML1.

That is, a user in the traveling direction side of the light beam L1 can visually-recognize light beams emitted from the display element DE1a but hardly visually-recognizes light beams emitted from the display elements DE1b and DE1c. A user in the traveling direction side of the light beam L2 can visually-recognize light beams emitted from the display element DE1b but hardly visually-recognizes light beams emitted from the display elements DE1a and DE1c. A user in the traveling direction side of the light beam L3 can visually-recognize light beams emitted from the display element DE1c but hardly visually-recognizes light beams emitted from the display elements DE1a and DE1b.

In the display device DSP in the first mode, the display element DE1a emits light, but the display elements DE1b and DE1c do not emit light. Therefore, a user in the traveling direction side of the light beam L1 can sufficiently visually-recognize an image displayed in the display device DSP, but a user in the traveling direction side of any of the light beams L2 and L3 hardly visually-recognizes the image. That is, the first mode limits the viewing angle of the display device DSP.

In contrast, in the display device DSP in the second mode, the display elements DE1a, DE1b, and DE1c all emit light. Therefore, users in the traveling direction side of all of the light beams L1, L2, and L3 can sufficiently visually-recognize the image. That is, the second mode has a broader viewing angle of the display device DSP than that of the first mode. Therefore, switching between the first mode and the second mode can control the viewing angle of the display device DSP.

All of the display devices that can be implemented by a person of ordinary skill in the art through arbitrary design changes to the display device described above as the embodiment of the present invention come within the scope of the present invention as long as they are in keeping with the spirit of the present invention.

Various types of the modified examples are easily conceivable within the category of the ideas of the present invention by a person of ordinary skill in the art and the modified examples are also considered to fall within the scope of the present invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is:

1. A display device comprising:
a substrate;
an insulating layer provided above the substrate;
a first lower electrode and a second lower electrode, which are provided on the insulating layer and are spaced apart from each other;
a rib overlapping the first lower electrode and the second lower electrode and having a single pixel aperture;
a partition, which includes a lower portion provided above the rib and having a conductivity and an upper portion provided on the lower portion and having an aperture surrounded by an edge portion projecting from a side surface of the lower portion;
an organic layer in contact with the first lower electrode and the second lower electrode through the pixel aperture and including a light emitting layer;
an upper electrode covering the organic layer and in contact with the lower portion; and
a lens having a convex shape projecting toward a side opposite to the substrate and overlapping the aperture, wherein
the organic layer is in contact with the insulating layer through the pixel aperture between the first lower electrode and the second lower electrode.

2. The display device of claim 1, wherein
the organic layer includes a first area in contact with the first lower electrode and a second area in contact with the second lower electrode, and
the display device has a first mode in which the first area emits light and a second mode in which the first area and the second area emit light.

3. The display device of claim 2, further comprising:
a drive transistor;
a first display element serially connected to the drive transistor and including the first lower electrode;
a second display element parallely connected to the first display element and including the second lower electrode; and
a switching element provided between the drive transistor and the second display element, wherein
the switching element is configured such that the drive transistor and the second lower electrode are not conductive to each other in the first mode and the drive transistor and the second lower electrode are conductive to each other in the second mode.

4. The display device of claim 2, wherein
the first lower electrode is surrounded by the second lower electrode.

5. The display device of claim 2, wherein
the first lower electrode and the second lower electrode are arranged in a direction, the direction intersecting a center line of the lens.

6. The display device of claim 2, wherein
the first lower electrode and the second lower electrode are arranged in a first direction, and
a cross-sectional shape along the first direction and a second direction intersecting the first direction of the lens is a convex shape projecting toward a side opposite to the substrate.

7. The display device of claim 6, wherein
a principal point of the lens overlaps the first lower electrode in plan view.

8. The display device of claim 2, wherein
a center line of the lens overlaps the first lower electrode in plan view.

9. The display device of claim 3, further comprising:
a third lower electrode provided on the insulating layer, spaced apart from the first lower electrode and the second lower electrode, and electrically connected to the second lower electrode, wherein
the pixel aperture overlaps the third lower electrode,
the first lower electrode is provided between the second lower electrode and the third lower electrode, and
the organic layer is in contact with the third lower electrode through the pixel aperture and in contact with the insulating layer between the first lower electrode and the third lower electrode and between the second lower electrode and the third lower electrode.

10. The display device of claim 9, wherein
a direction in which the first lower electrode, the second lower electrode, and the third lower electrode are arranged intersects a center line of the lens.

11. The display device of claim 9, wherein
a center line of the lens overlaps the first lower electrode in plan view.

12. The display device of claim 1, wherein
the lens has a first lens edge and a second lens edge, which are parallel to a center line of the lens, and
the first lens edge and the second lens edge overlap the partition in plan view.

13. The display device of claim 12, further comprising:
a light-shielding layer overlapping the first lens edge and the second lens edge in plan view.

14. The display device of claim 1, further comprising:
a cap layer provided on the upper electrode;
a first organic insulating layer provided on the cap layer;
a sealing layer provided on the first organic insulating layer and formed of an inorganic material; and
a second organic insulating layer provided between the sealing layer and the lens, wherein
the second organic insulating layer is thicker than the first organic insulating layer.

15. The display device of claim 1, wherein
the lens is formed of a transparent resin material.
